(19) United States
(12) Patent Application Publication
(10) Pub. No.: US 2024/0266272 A1
(43) Pub. Date: Aug. 8, 2024

(54) INTERPOSER, METHOD OF DESIGNING INTERPOSER, AND METHOD OF MANUFACTURING INTERPOSER

(71) Applicant: SAMSUNG ELECTRONICS CO., LTD., Suwon-si (KR)

(72) Inventor: Janghee BAE, Suwon-si (KR)

(73) Assignee: SAMSUNG ELECTRONICS CO., LTD., Suwon-si (KR)

(21) Appl. No.: 18/409,547

(22) Filed: Jan. 10, 2024

(30) Foreign Application Priority Data
Feb. 6, 2023 (KR) 10-2023-0015717

(51) Int. Cl. H01L 23/498; H01L 23/00; H01L 23/48; H01L 25/00; H01L 25/065

(52) U.S. Cl. CPC H01L 23/49838; H01L 23/481; H01L 23/49816; H01L 23/49822; H01L 24/16; H01L 25/0655; H01L 25/50; H01L 2224/16227; H01L 2224/16238; H01L 2924/15311

(57) ABSTRACT

Provided is a method of manufacturing an interposer, the method including providing a design of the interposer, and manufacturing the interposer based the design of the interposer, wherein the interposer includes bump pads contacting external connection bumps and spaced apart from each other at a distance greater than a pad interval, wherein the providing the design of the interposer includes generating a library including information about library pads having different dimensions, and determining a layout of the bump pads corresponding to each of the pad regions, wherein the layout of the bump pads corresponding to each of the pad regions is determined by selecting a library pad from among the library pads having a target dimension based on the pad interval and a pitch distance of target points in each of the pad regions, and placing the selected library pad at the target points in each of the pad regions.

### CROSS-REFERENCE TO RELATED APPLICATION

This application is based on and claims priority to Korean Patent Application No. 10-2023-0015717, filed on Feb. 6, 2023, in the Korean Intellectual Property Office, the disclosure of which is incorporated by reference herein in its entirety.

### BACKGROUND

Embodiments of the present disclosure relate to an interposer, a method of designing an interposer, and a method of manufacturing an interposer.

The design of a semiconductor device includes determining a layout of each component of the semiconductor device through a manual operation by an operator, determining whether the determined layout of each component of the semiconductor device conforms to a design rule, and modifying the layout of each component of the semiconductor device depending on a result of determining whether the determined layout conforms to the design rule. As semiconductor devices are required to be multifunctional, the design of semiconductor devices is becoming more complex and the time and cost for designing semiconductor devices are gradually increasing.

### SUMMARY

One or more embodiments provide an interposer.

One or more embodiments also provide a method of designing an interposer and a method of manufacturing an interposer including the same.

According to an aspect of an embodiment, there is provided a method of manufacturing an interposer, the method including providing a design of the interposer, and manufacturing the interposer based the design of the interposer, wherein the interposer includes bump pads contacting external connection bumps and spaced apart from each other at a distance greater than a pad interval, wherein the providing the design of the interposer includes generating a library including information about library pads having different dimensions, and determining a layout of the bump pads corresponding to each of the pad regions, wherein the layout of the bump pads corresponding to each of the pad regions is determined by selecting a library pad from among the library pads having a target dimension based on the pad interval and a pitch distance of target points in each of the pad regions, and placing the selected library pad at the target points in each of the pad regions.

According to another aspect of an embodiment, there is provided a method of designing an interposer, the method including generating a library including information about library pads having different dimensions, determining a layout of the bump pads corresponding to each of the pad regions, the layout of the bump pads corresponding to each of the pad regions being determined based on selecting a library pad having a target dimension from among the library pads based on the pad interval and a pitch distance of the external connection bumps overlapping each of the pad regions, and placing the selected library pad at target points in each of the pad regions, and generating a layout drawing of the bump pads based on the determined layout of the bump pads, wherein the interposer is configured to electrically connect a semiconductor chip mounted on the interposer and external connection bumps attached to bump pads of the interposer, and wherein the bump pads are spaced apart from each other at a distance greater than the pad interval on a reference plane.

According to another aspect of an embodiment, there is provided an interposer including a base substrate, an interconnect structure on the base substrate and including a conductive interconnect pattern, through electrodes penetrating the base substrate, bump pads under the base substrate and spaced apart from each other at an interval greater than a pad interval, and external connection bumps on the bump pads, respectively, wherein the bump pads includes first bump pads spaced at a first pitch distance in a first pad region and respectively having a first length in a first direction, and second bump pads spaced at a second pitch distance that is greater than the first pitch distance in a second pad region and respectively having a second length that is greater than the first length in the first direction.

### BRIEF DESCRIPTION OF DRAWINGS

Embodiments will be more clearly understood from the following detailed description taken in conjunction with the accompanying drawings in which:

FIG. 1 is a cross-sectional view of a semiconductor package including an interposer according to embodiments;

FIG. 2 is a plan view of a layout of bump pads according to embodiments;

FIG. 3 is a plan view of a layout of bump pads according to embodiments:

FIG. 4 is a flowchart of a method of determining a layout of bump pads, according to embodiments:

FIG. 5 is a plan view for illustrating a method of determining a layout of bump pads, according to embodiments:

FIG. 6 is a flowchart of a method of designing an interposer according to embodiments:

FIG. 7 is a flowchart of a method of manufacturing an interposer according to embodiments; and

FIGS. 8A, 8B, 8C, 8D, 8E, and 8F are cross-sectional views illustrating a stage of manufacturing the interposer of FIG. 7 according to embodiments.

### DETAILED DESCRIPTION

Hereinafter, embodiments will be described in detail with reference to the accompanying drawings. The same reference numerals are used for the same components in the drawings, and duplicate descriptions thereof are omitted.

Embodiments described herein are example embodiments, and thus, the disclosure is not limited thereto.

In this specification, a vertical direction may be defined as a Z direction, and a horizontal direction may be defined as a direction perpendicular to the Z direction. A first horizontal direction may cross a second horizontal direction. The first horizontal direction may be referred to as an X direction, and the second horizontal direction may be referred to as a Y direction. A vertical level may refer to a height level in the vertical direction. A dimension of a component may refer to a length of the component in a horizontal direction, a length of the component in a vertical direction, a diameter of the component, a length of the component in a major axis direction, a length of the component in a minor axis direction, and/or a planar area of the component. A pitch distance may refer to a length in a horizontal direction between centers of two neighboring components among components having a regular arrangement.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

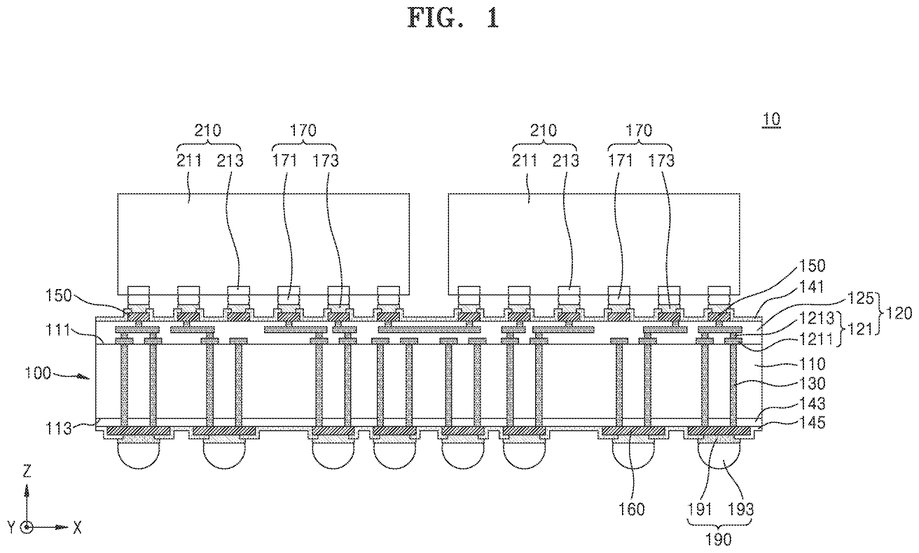

FIG. 1 is a cross-sectional view of a semiconductor package 10 including an interposer 100 according to embodiments.

Referring to FIG. 1, the semiconductor package 10 may include the interposer 100 and a plurality of semiconductor chips 210 mounted on the interposer 100. The interposer 100 may provide an electrical connection path electrically connecting each of the plurality of semiconductor chips 210 and external connection bumps 190 provided on the lower side of the interposer 100 and an electrical connection path electrically connecting the plurality of semiconductor chips 210 to one another.

In some embodiments, the interposer 100 may include a base substrate 110, an interconnect structure 120, through electrodes 130, an upper protective layer 141, upper conductive pads 150, a first lower protective layer 143, bump pads 160, a second lower protective layer 145, and external connection bumps 190.

The interconnect structure 120 may be disposed on a first surface 111 of the base substrate 110 and may include an insulating layer 125 disposed on and covering the first surface 111 of the base substrate 110, and a conductive interconnect pattern 121 covered by the insulating layer 125. For example, the insulating layer 125 may include at least one of oxide and nitride. For example, the insulating layer 125 may include at least one of silicon oxide and silicon nitride.

The conductive interconnect pattern 121 may include a plurality of conductive layers 1211 at different vertical levels within the insulating layer 125 to form a multilayer structure, and conductive vias 1213 extending in the vertical direction within the insulating layer 125 to interconnect the plurality of conductive layers 1211 to one another. For example, each of the plurality of conductive layers 1211 and the conductive vias 1213 may include at least one metal selected from tungsten (W), aluminum (Al), and copper (Cu).

The upper conductive pads 150 may be disposed on a top surface of the interconnect structure 120. The upper conductive pads 150 may be spaced apart from each other in the horizontal direction (e.g., X direction and/or Y direction) on the top surface of the interconnect structure 120. Each of the upper conductive pads 150 may be electrically connected to at least one of the through electrodes 130 through the conductive interconnect pattern 121 of the interconnect structure 120. The upper conductive pads 150 may include, for example, at least one metal selected from W, Al, and Cu.

The upper protective layer 141 may cover the top surface of the interconnect structure 120 and may cover portions of each of the upper conductive pads 150. The upper protective layer 141 may cover sidewalls and portions of the top surface each of the upper conductive pads 150. The upper protective layer 141 may include openings exposing the remaining portions of the top surface of each of the upper conductive pads 150. For example, the upper protective layer 141 may include silicon oxide, silicon nitride, or a combination thereof.

Each of the semiconductor chips 210 may be mounted on the interposer 100 through chip connection bumps 170. Each of the semiconductor chips 210 may be mounted on the interposer 100 in a flip chip manner. Each of the semiconductor chips 210 may include a semiconductor substrate 211 and chip pads 213 provided in the lower side of the semiconductor substrate 211. The chip connection bumps 170 may be between the chip pads 213 of the semiconductor chips 210 and the upper conductive pads 150 of the interposer 100 and may electrically connect the chip pads 213 of the semiconductor chips 210 to the upper conductive pads 150 of the interposer 100. In some embodiments, each of the chip connection bumps 170 may include an upper connection pillar 173 connected to the upper conductive pad 150 through the opening of the upper protective layer 141, and an upper solder layer 171 between the upper connection pillar 173 and the chip pad 213. The upper connection pillar 173 may include nickel (Ni), Cu, palladium (Pd), platinum (Pt), gold (Au), or a combination thereof. In some cases, the upper connection pillar 173 may be omitted.

The first lower protective layer 143 may extend along a second surface 113 of the base substrate 110 to cover the second surface 113 of the base substrate 110. The first lower protective layer 143 may include top and bottom surfaces that are opposite to each other. The top surface of the first lower protective layer 143 may contact the base substrate 110, and the bottom surface of the first lower protective layer 143 may contact the second lower protective layer 145 and the bump pads 160. In addition, the first lower protective layer 143 may cover sidewalls of the through electrode 130 protruding from the second surface 113 of the base substrate 110. In some embodiments, the bottom surface of the first lower protective layer 143 may be on the same plane as the bottom surfaces of the through electrodes 130 contacting the bump pads 160. For example, the first lower protective layer 143 may include at least one of oxide and nitride. For example, the first lower protective layer 143 may include at least one of silicon oxide and silicon nitride. In some embodiments, the first lower protective layer 143 may have a multilayer structure in which a plurality of insulating films are stacked. For example, the first lower protective layer 143 may include a silicon oxide film and a silicon nitride film sequentially stacked on the second surface 113 of the base substrate 110.

The bump pads 160 may be disposed on the bottom surface of the first lower protective layer 143. For example, the bump pads 160 may be respectively connected to the external connection bumps 190. The bump pads 160 may be arranged to be spaced apart from each other in the horizontal direction (e.g., X direction and/or Y direction) on the bottom surface of the first lower protective layer 143. The bump pads 160 may include, for example, at least one metal selected from W, Al, or Cu.

In some embodiments, the bump pads 160 may have a uniform thickness in the vertical direction (Z direction). The top surfaces of the bump pads 160 may contact the first lower protective layer 143 and the through electrodes 130, and the bottom surfaces of the bump pads 160 may contact the external connection bumps 190. The top and the bottom surfaces of the bump pads 160 may be flat. In some embodiments, when viewing a cross-section, each of the bump pads 160 may have a rectangular shape. In some embodiments, in a plan view, each of the bump pads 160 may have, for example, a circular or elliptical shape. In some embodiments, in a plan view, each of the bump pads 160 may have, for example, a quadrangular shape.

The bump pads 160 may be arranged in the first horizontal direction (X direction) and the second horizontal direction (Y direction) on a reference plane (e.g., the bottom surface of the first lower protective layer 143) within the interposer 100 perpendicular to the vertical direction and may be spaced apart from each other at a distance greater than a predetermined minimum pad interval in each of the first horizontal direction (X direction) and the second horizontal direction (Y direction). The bump pads 160 may include a plurality of bump pads 160 having different dimensions (e.g., a length in the first horizontal direction (X direction) and/or a length in the second horizontal direction (Y direction)).

In some embodiments, the dimensions and pitch distances of the bump pads 160 may be different for each region of the reference plane. For example, the pitch distance of the bump pads 160 in a first pad region of the reference plane may be greater than the pitch distance of the bump pads 160 in a second pad region of the reference plane, and the dimension of the bump pads 160 in the first pad region of the reference plane may be greater than the dimension of the bump pads 160 in the second pad region of the reference plane. The pitch distance of the bump pads 160 for each region may correspond to the pitch distance of the external connection bumps 190 in the corresponding region. For example, the pitch distance of the bump pads 160 in the first pad region may be the same as the pitch distance of the external connection bumps 190 in a region overlapping the first pad region, and the pitch distance of the bump pads 160 in the second pad region may be the same as the pitch distance of the external connection bumps 190 in a region overlapping the second pad region.

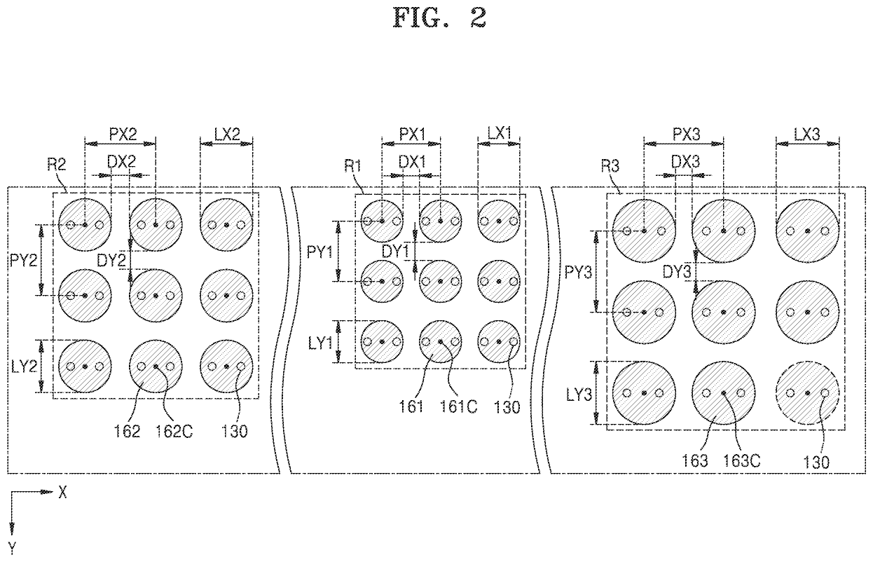

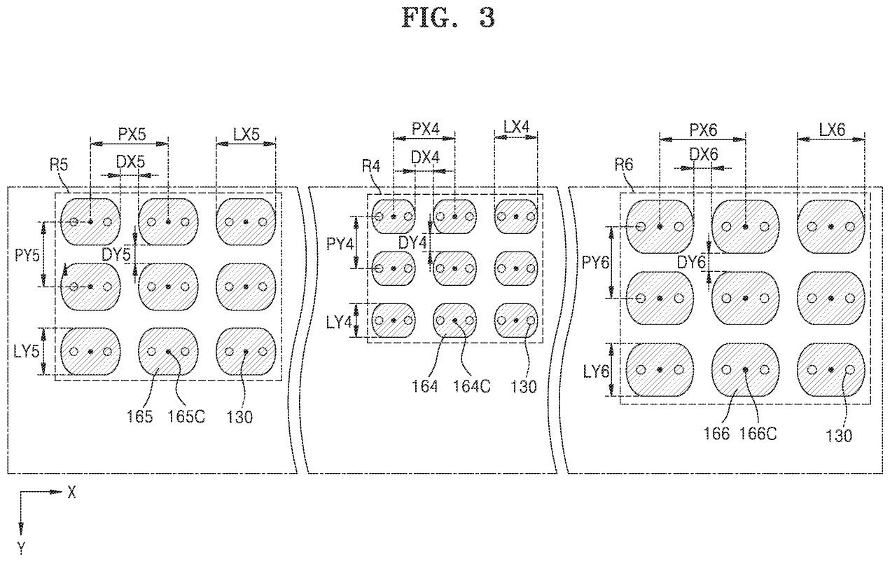

In some embodiments, the layout of the bump pads 160 may be determined based on the dimension of the bump pads 160, the pitch distance of the bump pads 160, the distance between the bump pads 160, and/or the predetermined minimum pad interval. The layout of the bump pads 160 is described below in detail with reference to FIGS. 2 and 3.

The second lower protective layer 145 may extend along the bottom surface of the first lower protective layer 143 to cover the bottom surface of the first lower protective layer 143 and may also extend along portions of the bottom surface and sidewalls of each of the bump pads 160. The second lower protective layer 145 may include openings exposing other portions of the bottom surface of each of the bump pads 160. The second lower protective layer 145 may include a material that is different from that of the first lower protective layer 143. The first lower protective layer 143 may include an inorganic insulating material and the second lower protective layer 145 may include an organic insulating material. In some embodiments, the second lower protective layer 145 may include polyimide.

The interposer 100 may be mounted on a board (e.g., a printed circuit board) provided on the lower side of the interposer 100 through the external connection bumps 190. The external connection bumps 190 may be arranged between the bump pads 160 of the interposer 100 and the board, and may electrically and physically connect the board to the bump pads 160 of the interposer 100. In some embodiments, each of the external connection bumps 190 may include a connection pillar 191 connected to the bump pad 160 through the opening of the second lower protective layer 145, and a solder layer 193 between the connection pillar 191 and the board. The connection pillar 191 may include nickel (Ni), copper (Cu), palladium (Pd), platinum (Pt), gold (Au), or a combination thereof. In some cases, the connection pillar 191 may be omitted.

The through electrodes 130 may be configured to electrically connect the conductive interconnect pattern 121 of the interconnect structure 120 to the bump pads 160. The through electrodes 130 may extend from the first surface 111 to the second surface 113 of the base substrate 110 and vertically penetrate the base substrate 110. In addition, the through electrodes 130 may further penetrate the first lower protective layer 143 on the second surface 113 of the base substrate 110. An upper end of each through electrode 130 may be connected to the conductive interconnect pattern 121 of the interconnect structure 120, and a lower end of each through electrode 130 may be connected to the bump pad 160.

For example, the through electrode 130 may include a columnar conductive plug penetrating the base substrate 110 and the first lower protective layer 143 and a cylindrical conductive barrier film surrounding sidewalls of the conductive plug. The conductive barrier film may include at least one material selected from titanium (Ti), titanium nitride (TiN), tantalum (Ta), TaN, ruthenium (Ru), cobalt (Co), manganese (Mn), WN, Ni, and nickel boride (NiB), and the conductive plug may include at least one material selected from a Cu alloy such as Cu, copper tin (CuSn), copper magnesium (CuMg), copper nickel (CuNi), copper zinc (CuZn), copper palladium (CuPd), copper gold (CuAu), copper rhenium (CuRe), CuW, W, W alloy, Ni, ruthenium (Ru), and cobalt (Co). A via insulating film may be between the base substrate 110 and the through electrode 130. The via insulating film may include an oxide film, a nitride film, a carbide film, a polymer, or a combination thereof.

In some embodiments, the interposer 100 may have a redundant via structure in which two or more through electrodes 130 are connected to one bump pad 160. When one of the two or more through electrodes 130 is defective, the electrical connection of the interposer 100 may be prevented from being defective by the operation of the other through electrodes 130.

FIG. 2 is a plan view of a layout of the bump pads 160 according to embodiments.

Referring to FIGS. 1 and 2, the interposer 100 may include first bump pads 161 in a first pad region R1 of the reference plane, second bump pads 162 in a second pad region R2 of the reference plane, and third bump pads 163 in a third pad region R3 of the reference plane. The external connection bumps 190 may include first external connection bumps arranged in a region overlapping the first pad region R1 and connected to the first bump pads 161, second external connection bumps arranged in a region overlapping the second pad region R2 and connected to the second bump pads 162, and third external connection bumps arranged in a region overlapping the third pad region R3 and connected to the third bump pads 163.

An X1 pitch distance PX1 of the first bump pads 161 in the first horizontal direction (X direction) and a Y1 pitch distance PY1 of the first bump pads 161 in the second horizontal direction (Y direction) may be the same as a pitch distance of the first external connection bumps in the first horizontal direction (X direction) and a pitch distance of the first external connection bumps in the second horizontal direction (Y direction), respectively. An X2 pitch distance PX2 of the second bump pads 162 in the first horizontal direction (X direction) and a Y2 pitch distance PY2 of the second bump pads 162 in the second horizontal direction (Y direction) may be the same as a pitch distance of the second external connection bumps in the first horizontal direction (X direction) and a pitch distance of the second external connection bumps in the second horizontal direction (Y direction), respectively. An X3 pitch distance PX3 of the third bump pads 163 in the first horizontal direction (X direction) and a Y3 pitch distance PY3 of the third bump pads 163 in the second horizontal direction (Y direction) may be the same as a pitch distance of the third external connection bumps in the first horizontal direction (X direction) and a pitch distance of the third external connection bumps in the second horizontal direction (Y direction), respectively. The X1 pitch distance PX1 is a distance between center points 161C of the first bump pads 161 neighboring in the first horizontal direction (X direction) and the Y1 pitch distance PY1 is a distance between the center points 161C of the first bump pads 161 neighboring in the second horizontal direction (Y direction). The X2 pitch distance PX2 is a distance between center points 162C of the second bump pads 162 neighboring in the first horizontal direction (X direction) and the Y2 pitch distance PY2 is a distance between the center points 162C of the second bump pads 162 neighboring in the second horizontal direction (Y direction). The X3 pitch distance PX3 is a distance between center points 163C of the third bump pads 163 neighboring in the first horizontal direction (X direction) and the Y3 pitch distance PY3 is a distance between the center points 163C of the third bump pads 163 neighboring in the second horizontal direction (Y direction). The dimension of each second bump pad 162 may be larger than the dimension of each first bump pad 161 and the dimension of each third bump pad 163 may be larger than the dimension of each second bump pad 162.

In the first pad region R1, each of the first bump pads 161 may have an X1 length LX1 in the first horizontal direction (X direction) and a Y1 length LY1 in the second horizontal direction (Y direction). In the first pad region R1, the first bump pads 161 may be spaced apart from each other at a distance greater than the minimum pad interval in the first horizontal direction (X direction) and the second horizontal direction (Y direction). For example, an interval DX1 between two first bump pads 161 neighboring in the first horizontal direction (X direction) and an interval DY1 between two first bump pads 161 neighboring in the second horizontal direction (Y direction) may be greater than the minimum pad interval. For example, the minimum pad interval may be a value selected from 5 μm to 30 μm.

In the second pad region R2, each of the second bump pads 162 may have an X2 length LX2 in the first horizontal direction (X direction) and a Y2 length LY2 in the second horizontal direction (Y direction). The X2 pitch distance PX2 may be greater than the X1 pitch distance PX1 and the Y2 pitch distance PY2 may be greater than the Y1 pitch distance PY1. The X2 length LX2 may be greater than the X1 length LX1 and the Y2 length LY2 may be greater than the Y1 length LY1. In the second pad region R2, the second bump pads 162 may be spaced apart from each other at a distance greater than the minimum pad interval in the first horizontal direction (X direction) and the second horizontal direction (Y direction). For example, an interval DX2 between two second bump pads 162 neighboring in the first horizontal direction (X direction) and an interval DY2 between two second bump pads 162 neighboring in the second horizontal direction (Y direction) may be greater than the minimum pad interval.

In the third pad region R3, each of the third bump pads 163 may have an X3 length LX3 in the first horizontal direction (X direction) and a Y3 length LY3 in the second horizontal direction (Y direction). The X3 pitch distance PX3 may be greater than the X2 pitch distance PX2 and the Y3 pitch distance PY3 may be greater than the Y2 pitch distance PY2. The X3 length LX3 may be greater than the X2 length LX2 and the Y3 length LY3 may be greater than the Y2 length LY2. In the third pad region R3, the third bump pads 163 may be spaced apart from each other at a distance greater than the minimum pad interval in the first horizontal direction (X direction) and the second horizontal direction (Y direction). For example, an interval DX3 between two third bump pads 163 neighboring in the first horizontal direction (X direction) and an interval DY3 between two third bump pads 163 neighboring in the second horizontal direction (Y direction) may be greater than the minimum pad interval.

In some embodiments, the first bump pads 161 may be provided in a region required to have a relatively small pitch. In some embodiments, each of the first bump pads 161 may be an input/output (I/O) pad configured to transmit data I/O signals to the semiconductor chip 210. In some embodiments, each of the second bump pads 162 and each of the third bump pads 163 may be power pads configured to transmit power signals (e.g., positive supply voltage, negative supply voltage, and/or ground voltage) to the semiconductor chip 210. In some embodiments, each of the second bump pads 162 and each of the third bump pads 163 may be dummy pads which are not electrically connected to the semiconductor chip 210. In some embodiments, each of the second bump pads 162 may be power pads and each of the third bump pads 163 may be dummy pads.

In some embodiments, each of the first bump pads 161, each of the second bump pads 162, and each of the third bump pads 163 may all be dummy pads. In this case, warpage of the interposer 100 may be adjusted by adjusting the arrangement of each of the first bump pads 161, each of the second bump pads 162, and each of the third bump pads 163 having different dimensions.

FIG. 3 is a plan view of a layout of the bump pads 160 according to embodiments.

Referring to FIGS. 1 and 3, the interposer 100 may include fourth bump pads 164 in a fourth pad region R4 of the reference plane, fifth bump pads 165 within a fifth pad region R5 of the reference plane, and sixth bump pads 166 in a sixth pad region R6 of the reference plane. The fourth to sixth bump pads 164, 165, and 166 may each have an elliptical shape having major and minor axes. The external connection bumps 190 may include fourth external connection bumps arranged in a region overlapping the fourth pad region R4 and connected to the fourth bump pads 164, fifth external connection bumps arranged in a region overlapping the fifth pad region R5 and connected to the fifth bump pads 165, and sixth external connection bumps arranged in a region overlapping the sixth pad region R6 and connected to the sixth bump pads 166.

In the fourth pad region R4, the fourth bump pads 164 may be arranged to have an X4 pitch distance PX4 in the first horizontal direction (X direction) and a Y4 pitch distance PY4 in the second horizontal direction (Y direction), and each of the fourth bump pads 164 may have an X4 length LX4 in the first horizontal direction (X direction) and a Y4 length LY4 in the second horizontal direction (Y direction). The X4 pitch distance PX4 is a distance between center points 164C of the fourth bump pads 164 neighboring in a first horizontal direction (X direction) and the Y4 pitch distance PY4 is the distance between the center points 164C of the fourth bump pads 164 neighboring in the second horizontal direction (Y direction). The X4 pitch distance PX4 and the Y4 pitch distance PY4 may be the same as a pitch distance of the fourth external connection bumps in the first horizontal direction (X direction) and a pitch distance of the fourth external connection bumps in the second horizontal direction (Y direction), respectively. An interval DX4 between two fourth bump pads 164 neighboring in the first horizontal direction (X direction) and an interval DY4 between two fourth bump pads 164 neighboring in the second horizontal direction (Y direction) may be less than the minimum pad interval.

In the fifth pad region R5, the fifth bump pads 165 may be arranged to have an X5 pitch distance PX5 in the first horizontal direction (X direction) and a Y5 pitch distance PY5 in the second horizontal direction (Y direction), and each of the fifth bump pads 165 may have an X5 length LX5 in the first horizontal direction (X direction) and a Y5 length LY5 in the second horizontal direction (Y direction). The X5 pitch distance PX5 is a distance between center points 165C of the fifth bump pads 165 neighboring in the first horizontal direction (X direction) and the Y5 pitch distance PY5 is a distance between the center points 165C of the fifth bump pads 165 neighboring in the second horizontal direction (Y direction). The X5 pitch distance PX5 and the Y5 pitch distance PY5 may be the same as a pitch distance of the fifth external connection bumps in the first horizontal direction (X direction) and a pitch distance of the fifth external connection bumps in the second horizontal direction (Y direction) The X5 pitch distance PX5 may be greater than the X4 pitch distance PX4 and the Y5 pitch distance PY5 may be greater than the Y4 pitch distance PY4. The X5 length LX5 may be greater than the X4 length LX4 and the Y5 length LY5 may be greater than the Y4 length LY4. An interval DX5 between two fifth bump pads 165 neighboring in the first horizontal direction (X direction) and an interval DY5 between two fifth bump pads 165 neighboring in the second horizontal direction (Y direction) may be greater than the minimum pad interval.

In the sixth pad region R6, the sixth bump pads 166 may be arranged to have an X6 pitch distance PX6 in the first horizontal direction (X direction) and a Y6 pitch distance PY6 in the second horizontal direction (Y direction), and each of the sixth bump pads 166 may have an X6 length LX6 in the first horizontal direction (X direction) and a Y6 length LY6 in the second horizontal direction (Y direction). The X6 pitch distance PX6 is a distance between center points 166C of the sixth bump pads 166 neighboring in the first horizontal direction (X direction) and the Y6 pitch distance PY6 is a distance between the center points 166C of the sixth bump pads 166 neighboring in the second horizontal direction (Y direction). The X6 pitch distance PX6 and the Y6 pitch distance PY6 may be the same as a pitch distance of the sixth external connection bumps in the first horizontal direction (X direction) and a pitch distance of the sixth external connection bumps in the second horizontal direction (Y direction), respectively. The X6 pitch distance PX6 may be greater than the X5 pitch distance PX5 and the Y6 pitch distance PY6 may be greater than the Y5 pitch distance PY5. The X6 length LX6 may be greater than the X5 length LX5 and the Y6 length LY6 may be greater than the Y5 length LY5. An interval DX6 between two sixth bump pads 166 neighboring in the first horizontal direction (X direction) and an interval DY6 between two sixth bump pads 166 neighboring in the second horizontal direction (Y direction) may be greater than the minimum pad interval.

In some embodiments, the fourth bump pads 164 may be provided in a region required to have a relatively small pitch. In some embodiments, each of the fourth bump pads 164 may be I/O pads configured to transmit data I/O signals to the semiconductor chip 210. In some embodiments, each of the fifth bump pads 165 and each of the sixth bump pads 166 may be power pads configured to transmit power signals (e.g., positive supply voltage, negative supply voltage, and/or ground voltage) to the semiconductor chip 210 or dummy pads which are not electrically connected to the semiconductor chip 210.

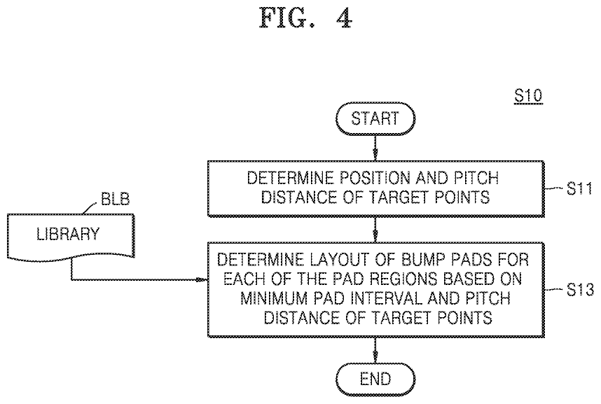

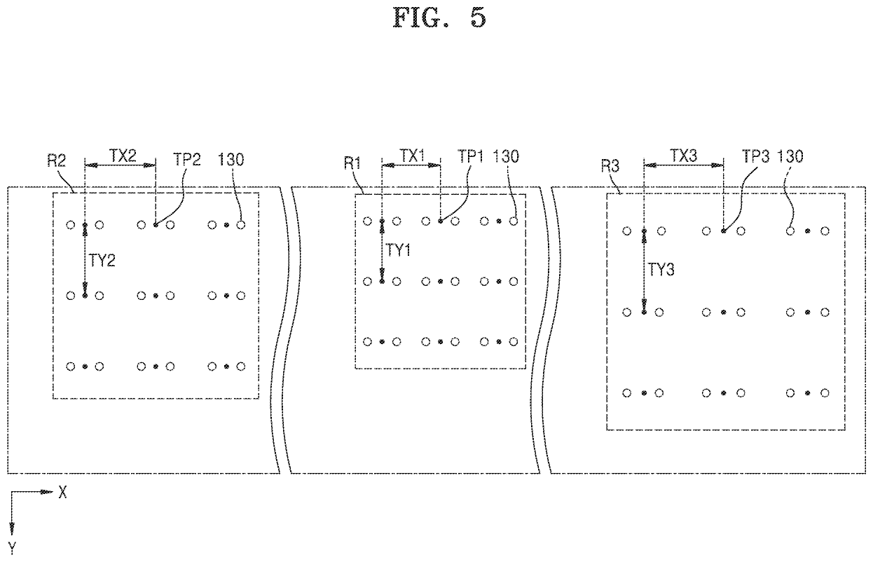

FIG. 4 is a flowchart of a method of determining a layout of the bump pads according to embodiments. FIG. 5 is a plan view for illustrating a method of determining a layout of the bump pads according to embodiments. Hereinafter, a method of determining the layout of the bump pads, according to embodiments, is described with reference to FIGS. 1, 2, 4, and 5.

Referring to FIGS. 4 and 5, the method (S10) of determining the layout of the bump pads 160 may include, on the reference plane of the interposer 100 on which the bump pads 160 are arranged, determining positions of target points and pitch distances of the target points for each region of the reference plane (step S11), where the target points are points where the bump pads 160 are located, and each of the target points may be aligned with the central point of each of the bump pads 160. The positions and pitch distances of the target points may be determined based on relative distances to other components (e.g., external connection bumps 190 and through electrodes 130). In some embodiments, the XY coordinate (i.e., the X coordinate and the Y coordinate) of each target point may be the same as the XY coordinate of a corresponding external connection bump 190 among the external connection bumps 190. In some embodiments, the pitch distance of the target points may be the same as the pitch distance of corresponding external connection bumps 190 among the external connection bumps 190.

In some embodiments, first target points TP1 in the first pad region R1 may have the X1 pitch distance TX1 in the first horizontal direction (X direction) and the Y1 pitch distance TY1 in the second horizontal direction (Y direction), second target points TP2 in the second pad region R2 may have the X2 pitch distance TX2 in the first horizontal direction (X direction) and the Y2 pitch distance TY2 in the second horizontal direction (Y direction), and third target points TP3 in the third pad region R3 may have the X3 pitch distance TX3 in the first horizontal direction (X direction) and the Y3 pitch distance TY3 in the second horizontal direction (Y direction). The X2 pitch distance TX2 may be greater than the X1 pitch distance TX1 and the X3 pitch distance TX3 may be greater than the X2 pitch distance TX2. The Y2 pitch distance TY2 may be greater than the Y1 pitch distance TY1 and the Y3 pitch distance TY3 may be greater than the Y2 pitch distance TY2.

Referring to FIGS. 2 and 4, the method (S10) of determining the layout of the bump pads 160 may include determining the layout of the bump pads 160 for each of the pad regions based on the predetermined minimum pad interval and the pitch distance of the target points (step S13). All pad regions may be determined to have the same minimum pad interval. The pitch distance corresponding to a region of target points for each of the pad regions may be the same as the pitch distance of the external connection bumps 190 in the region overlapping each of the pad regions. In step S13, the location of each bump pad 160 may be determined so that the center point of each bump pad 160 is aligned with a corresponding target point.

Step S13 may include receiving information about the bump pads 160 from a library BLB. The library BLB may include information about library bump pads having different dimensions. The library BLB may include a memory device configured to store information about library bump pads.

In some embodiments, the library bump pads included in the library BLB may include a first library bump pad having the same dimension and shape as the first bump pad 161 of FIG. 2, a second library bump pad having the same dimension and shape as the second bump pad 162 of FIG. 2, and a third library bump pad having the same dimension and shape as the third bump pad 163 of FIG. 2. According to another embodiment, the library bump pads included in the library BLB may include a fourth library bump pad having the same dimension and shape as the fourth bump pad 164 of FIG. 3, a fifth library bump pad having the same dimension and shape as the fifth bump pad 165 of FIG. 3, and a sixth library bump pad having the same dimension and shape as the sixth bump pad 166 of FIG. 3. Prior to step S13, the library BLB including information on two or more types of library bump pads having different dimensions may be generated.

For example, in step S13, information on first to third library bump pads may be provided from the library BLB, and which library bump pad among the first to third library bump pads is to be assigned to each of the pad regions based on the minimum pad interval and the pitch distance of the target points may be determined. In some embodiments, the smaller pitch distance of the target points, smaller dimension of the library bump pads may be assigned to the corresponding pad region. In some embodiments, the greater the pitch distance of the target points in each of the pad regions, greater dimension of the library bump pads may be assigned to the corresponding pad region. In addition, when selecting a library bump pad assigned to each of the pad regions, a condition that an interval between the bump pads 160 implemented as the selected library bump pads has a value greater than the minimum pad interval must be satisfied.

In step S13, to assign library bump pads of a target dimension to the target pad region, whether the pitch distance of target points in the target pad region (or the pitch distance of external connection bumps 190 in the region overlapping the target pad region) is within a reference range among predetermined reference ranges may be determined, and which of the library bump pads to assign to the target pad region based on the determination of the pitch distance may be determined. In some embodiments, to assign library bump pads of a target dimension to the target pad region, an X1 reference range, an X2 reference range, and an X3 reference range may be determined. The X1 reference range may be determined to be greater than a first reference value and less than or equal to a second reference value, the X2 reference range may be determined to be greater than the second reference value and less than or equal to a third reference value, and the X3 reference range may be determined to be greater than the third reference value and less than or equal to a fourth reference value. When the pitch distance of the target points in the first horizontal direction (X direction) in the target pad region (or the pitch distance of the external connection bumps 190 in the first horizontal direction (X direction) in the region overlapping the target pad region) is within the X1 reference range, the first library bump pad corresponding to the first bump pad 161 may be assigned to each of the target points in the target pad region. When the pitch distance of the target points in the first horizontal direction (X direction) in the target pad region is within the X2 reference range, the second library bump pad corresponding to the second bump pad 162 may be assigned to each of the target points in the target pad region. When the pitch distance of the target points in the first horizontal direction (X direction) in the target pad region is within the X3 reference range, the third library bump pad corresponding to the third bump pad 163 may be assigned to each of the target points in the target pad region.

In some embodiments, to assign library bump pads of a target dimension to the target pad region, a Y1 reference range, a Y2 reference range, and a Y3 reference range may be further determined in addition to the X1 reference range, the X2 reference range, and the X3 reference range. The Y1 reference range may be determined to be greater than a fifth reference value and less than or equal to a sixth reference value, the Y2 reference range may be determined to be greater than the sixth reference value and less than or equal to a seventh reference value, and the Y3 reference range may be determined to be greater than the seventh reference value and less than or equal to an eighth reference value. When the pitch distance of the target points in the first horizontal direction (X direction) in the target pad region is within the X1 reference range and the pitch distance of the target points in the second horizontal direction (Y direction) in the target pad region is within the Y1 reference range, the first library bump pad corresponding to the first bump pad 161 may be assigned to each of the target points in the target pad region. When the pitch distance of the target points in the first horizontal direction (X direction) in the target pad region is within the X2 reference range and the pitch distance of the target points in the second horizontal direction (Y direction) in the target pad region is within the Y2 reference range, the second library bump pad corresponding to the second bump pad 162 may be assigned to each of the target points in the target pad region. When the pitch distance of the target points in the first horizontal direction (X direction) in the target pad region is within the X3 reference range and the pitch distance of the target points in the second horizontal direction (Y direction) in the target pad region is within the Y3 reference range, the third library bump pad corresponding to the third bump pad 163 may be assigned to each of the target points in the target pad region.

In some embodiments, the X1 pitch distance PX1 and the Y1 pitch distance PY1 of the first target points TP1 in the first pad region may be within the X1 reference range and the Y1 reference range, respectively, the X2 pitch distance PX2 and the Y2 pitch distance PY2 of the second target points TP2 in the second pad region may be within the X2 reference range and the Y2 reference range, respectively, and the X3 pitch distance PX3 and the Y3 pitch distance PY3 of the third target points TP3 in the third pad region may be within the X3 reference range and the Y3 reference range, respectively. In step S13, the first library bump pad corresponding to the first bump pad 161 may be determined to be disposed on each of the first target points TP1 in the first pad region, the second library bump pad corresponding to the second bump pad 162 may be determined to be disposed on each of the second target points TP2 in the second pad region, and the third library bump pad corresponding to the third bump pad 163 may be determined to be disposed on each of the third target points TP3 in the third pad region.

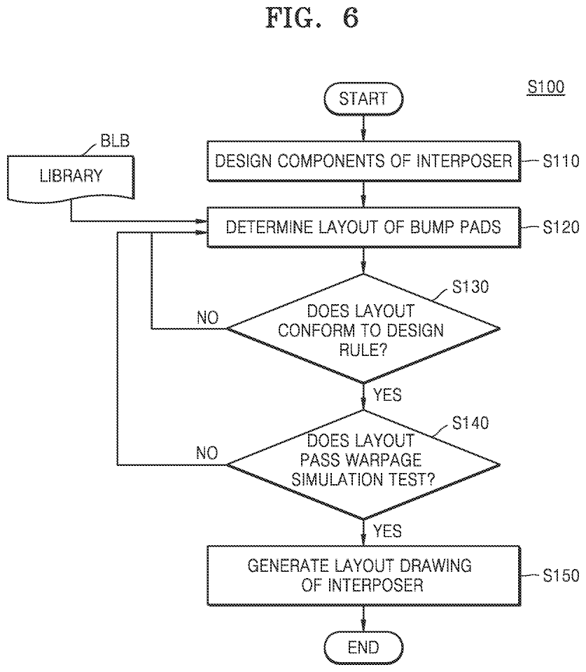

FIG. 6 is a flowchart of a method of designing the interposer 100, according to embodiments. Hereinafter, the method (S100) of designing the interposer 100, according to embodiments, is described with reference to FIGS. 1 and 2.

Referring to FIG. 6, the method (S100) of designing the interposer 100 may include designing the components of the interposer 100 (step S110), determining the layout of the bump pads 160 (step S120), determining whether the layout conforms to a design rule (step S130), performing a warpage simulation test (step S140), and generating a layout drawing of the interposer 100 (step S150).

In step S110, the layout of the components of the interposer 100, e.g., the interconnect structure 120, the through electrodes 130, the upper protective layer 141, the upper conductive pads 150, the first lower protective layer 143, the second lower protective layer 145, and the external connection bumps 190, may be determined.

The layout of the bump pads 160 in step S120 may be the same as the method of determining the layout of the bump pads 160 described above with reference to FIGS. 4 and 5 (S10). The layout of the bump pads 160 may be determined based on the minimum pad interval and the pitch distance between the target points in the target pad region determined by a design rule. The layout of the bump pads 160 may include selecting a library bump pad having a target dimension from among the library bump pads provided from the bump library BLB for each of the pad regions. To determine the layout of the bump pads 160 for the target pad region, the information on the library bump pads having different dimensions and shapes may be provided from the bump library BLB, and the library bump pad having the target dimension may be assigned to the target pad region based on the predetermined minimum pad interval and the pitch distance of the target points in the target pad region.

In step S130, whether the layout conforms to a design rule may be determined. For example, the design rule may include requirements for distances between patterns in the same layer, dimensions of patterns, and the like. In step S130, whether a distance between the bump pads 160 implemented by assigning the library bump pads has a value greater than the minimum pad interval in each of the pad regions may be determined. When the distance between the bump pads 160 is equal to or less than the minimum pad interval, step S120 may be performed again. When the distance between the bump pads 160 is greater than the minimum pad interval, step S140 may be performed.

In step S140, the warpage simulation test may be performed based on the design of the interposer 100. The warpage simulation may be performed by an appropriate tool capable of performing a simulation model (e.g., a computing device including a processor). When the warpage size detected (or predicted) in the warpage simulation exceeds a reference value, it may be determined that the design of the interposer 100 has not passed the warpage simulation test and step S120 may be performed again. When the warpage size detected (or predicted) in the warpage simulation is equal to or less than the reference value, it may be determined that the design of the interposer 100 has passed the warpage simulation test and step S150 may be performed.

In step S150, a layout drawing of the interposer 100 may be generated. The layout drawing of the interposer 100 may include information about a layout drawing for each layer of the interposer 100. The layout drawing of the interposer 100 may include a layout drawing (e.g., a 2D drawing) of the bump pads 160.

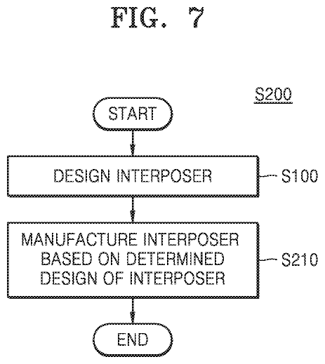

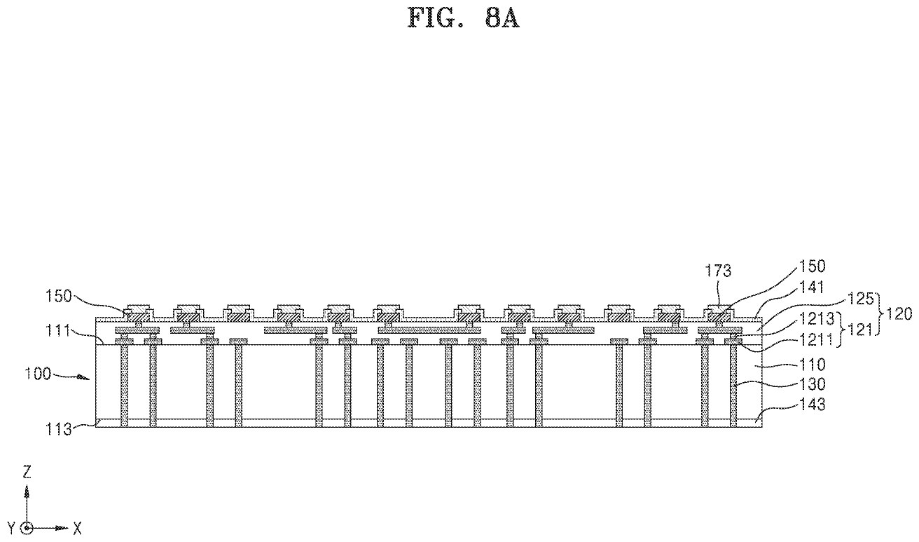

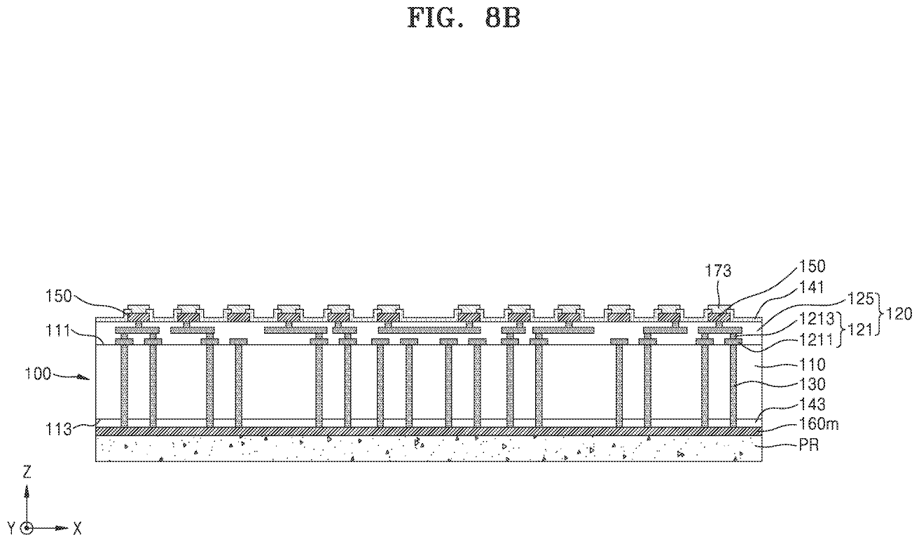

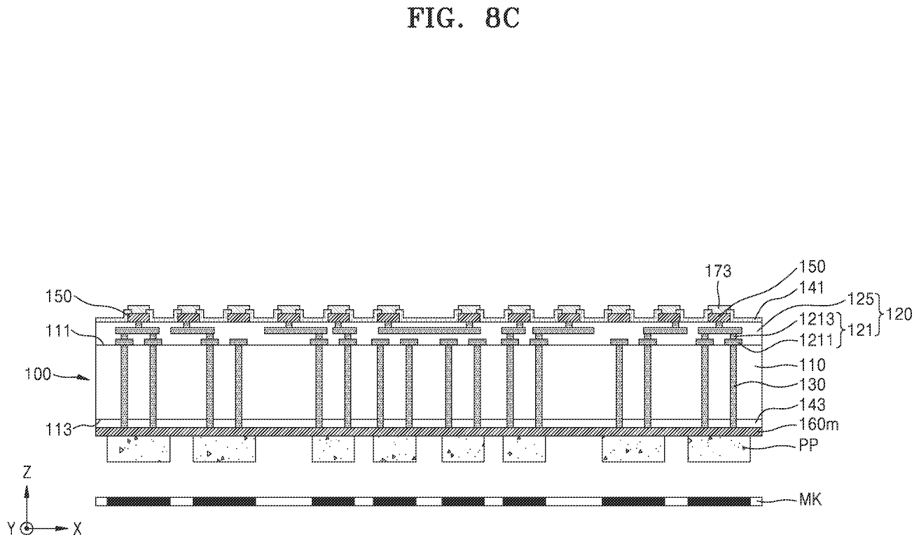

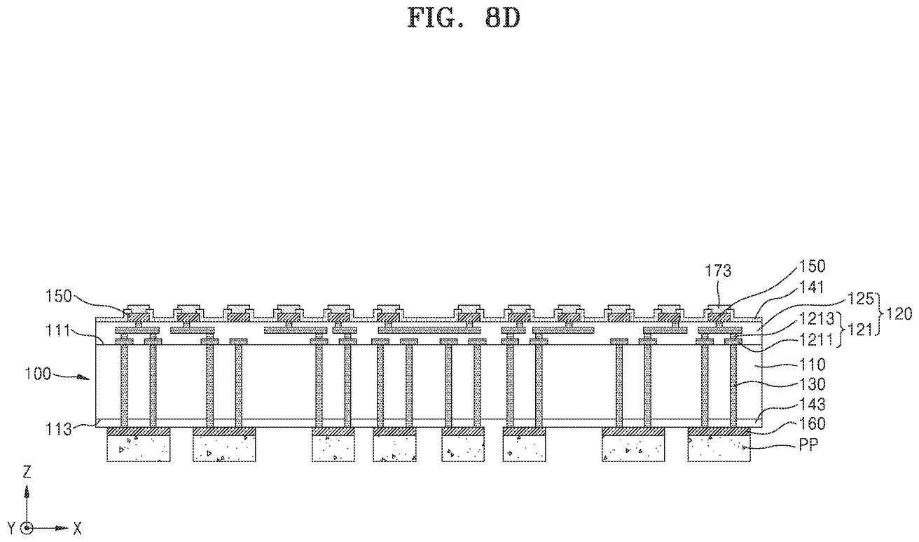

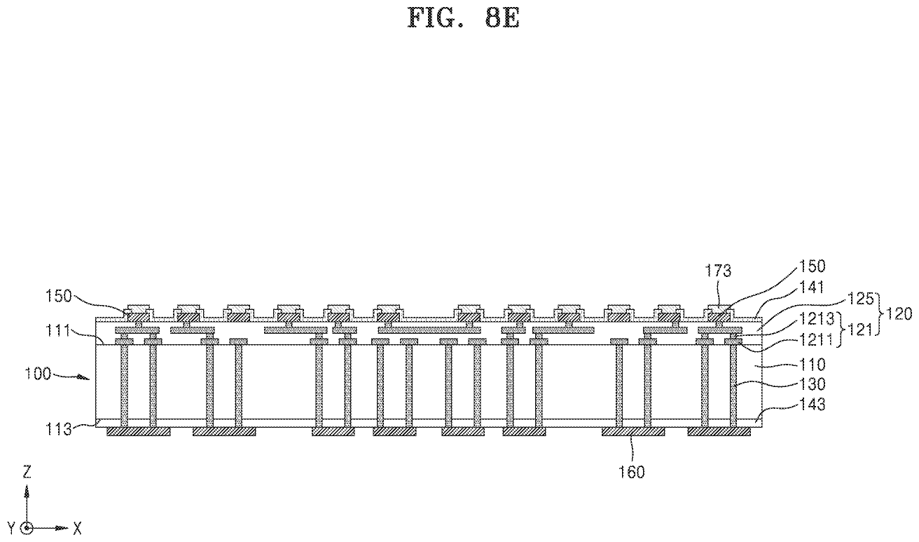

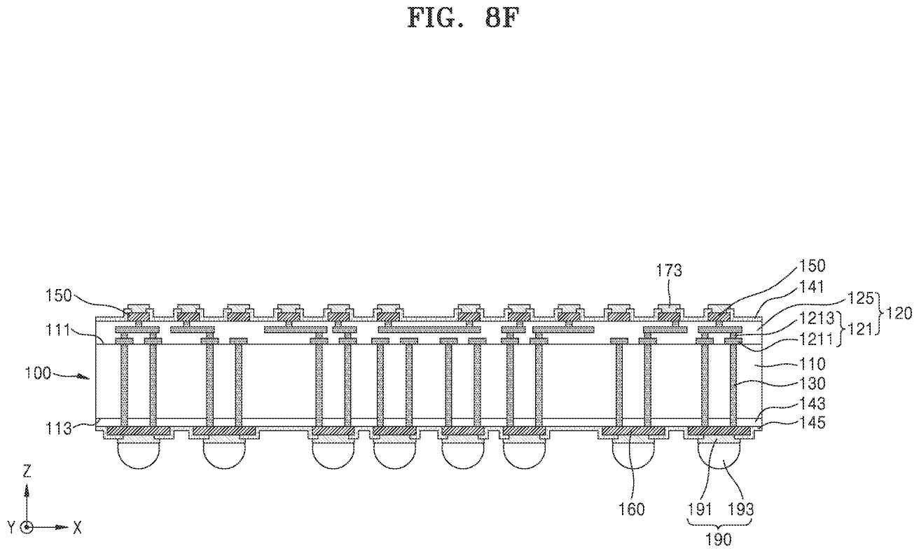

FIG. 7 is a flowchart of a method of manufacturing the interposer 100, according to embodiments. FIGS. 8A to 8F are cross-sectional views for illustrating a step (S210) of manufacturing the interposer of FIG. 7 according to embodiments.

Referring to FIG. 7, the method of manufacturing the interposer 100 (S200) may include designing the interposer 100 (step S100) and manufacturing the interposer 100 based on the design of the interposer 100 determined in the step of S100 (step S210).

Referring to FIG. 8A, the stage of manufacturing the interposer 100 (step S210) may include forming the through electrodes 130 on the base substrate 110, forming the interconnect structure 120 by performing a redistribution process on the first surface 111 of the base substrate 110, forming the upper conductive pads 150 on the interconnect structure 120, forming the upper protective layer 141 covering a portion of each upper conductive pad 150 and the interconnect structure 120, forming the upper connection pillar 173 on the upper conductive pad 150 exposed through the opening of the upper protective layer 141, and forming the first lower protective layer 143 extending along the second surface 113 of the base substrate 110. The first lower protective layer 143 may surround sidewalls of each of the through electrodes 130 protruding from the second surface 113 of the base substrate 110, and the bottom surface of the first lower protective layer 143 may be substantially coplanar with the bottom surfaces of the through electrodes 130. The bottom surface of the first lower protective layer 143 may be polished flat through a planarization process.

Referring to FIGS. 8B to 8E, the bump pads 160 may be formed on the bottom surface of the first lower protective layer 143. Hereinafter, a method of forming the bump pads 160 will be described with reference to FIGS. 8B to 8E.

Referring to FIG. 8B, a conductive film 160m extending along the bottom surface of the first lower protective layer 143 is formed, and a photoresist film PR extending along the bottom surface of the conductive film 160m is formed.

Referring to FIGS. 8B and 8C, a photomask MK for a photolithography process is prepared. The photo mask MK may be manufactured based on the layout drawing of the bump pads 160 generated in step S150 described with reference to FIG. 6.

The photolithography process using the photo mask MK is performed to pattern the photoresist film PR. As the photoresist film PR is patterned, a photoresist pattern PP is formed from the photoresist film PR. For example, the photolithography process may include performing an exposure process using the photo mask MK on the photoresist film PR and removing the exposed portion of the photoresist film PR through a developing process.

Referring to FIGS. 8C and 8D, the conductive film 160m may be patterned using the photoresist pattern PP as an etch mask. As the conductive film 160m is patterned, the bump pads 160 may be formed from the conductive film 160m.

Referring to FIGS. 8D and 8E, after forming the bump pads 160, the photoresist pattern PP may be removed. The photoresist pattern PP may be removed through, for example, a strip process.

Referring to FIG. 8F, the interposer 100 may manufactured by sequentially performing steps of forming the second lower protective layer 145 covering a portion of each bump pad 160 and the bottom surface of the first lower protective layer 143, forming the connection pillar 191 on the surface of the bump pad 160 exposed through the opening of the second lower protective layer 145, and forming the solder layer 193 on the surface of the connection pillar 191.

According to some embodiments, the layout of the bump pads of the interposer may be determined by generating a library with information about library bump pads of different dimensions and assigning the library bump pads prepared in the library to each of the pad regions of the interposer according to a predetermined rule (i.e., the minimum pad interval and the pitch distance of target points in each of the pad regions determined by the design rule). Accordingly, it is possible to reduce time and cost required for designing the interposer.

While embodiments have been described with reference to the figures, it will be understood by those of ordinary skill in the art that various changes in form and details may be made therein without departing from the spirit and scope as defined by the following claims and their equivalents.

What is claimed is:

1. A method of manufacturing an interposer, the method comprising:
providing a design of the interposer; and
manufacturing the interposer based the design of the interposer,
wherein the interposer comprises bump pads contacting external connection bumps and spaced apart from each other at a distance greater than a pad interval,
wherein the providing the design of the interposer comprises:
generating a library comprising information about library pads having different dimensions; and
determining a layout of the bump pads corresponding to each of the pad regions,
wherein the layout of the bump pads corresponding to each of the pad regions is determined by:
selecting a library pad from among the library pads having a target dimension based on the pad interval and a pitch distance of target points in each of the pad regions; and
placing the selected library pad at the target points in each of the pad regions.

2. The method of claim 1, wherein the library pads included in the library comprise:
a first library pad having a first length in a first direction;
a second library pad having a second length that is greater than the first length in the first direction; and
a third library pad having a third length that is greater than the second length in the first direction.

3. The method of claim 2, wherein the pad regions comprise:
a first pad region comprising first target points spaced at a first pitch distance in the first direction;
a second pad region comprising second target points spaced at a second pitch distance that is greater than the first pitch distance in the first direction; and
a third pad region comprising third target points spaced at a third pitch distance that is greater than the second pitch distance in the first direction, and
wherein the determining of the layout of the bump pads comprises
determining the first library pad as a bump pad at the first target points in the first pad region,
determining the second library pad as a bump pad at the second target points in the second pad region, and
determining the third library pad as a bump pad at the third target points in the third pad region.

4. The method of claim 3, wherein the interposer is configured to electrically connect a semiconductor chip mounted on the interposer and the external connection bumps on the lower side of the interposer,
wherein the first pad region comprises bump pads configured to transmit data I/O signals to the semiconductor chip, and
wherein at least one of the second pad region and the third pad region comprises bump pads configured to transmit power signals to the semiconductor chip.

5. The method of claim 2, wherein the determining of the layout of the bump pads for each of the pad regions comprises:
determining the first library pad as a bump pad at the target points in each of the pad regions based on the pitch distance of the target points in each of the pad regions being greater than a first reference value and less than or equal to a second reference value;
determining the second library pad as a bump pad at the target points in each of the pad regions based on the pitch distance of the target points in each of the pad regions being greater than the second reference value and less than or equal to a third reference value; and
determining the third library pad as a bump pad arranged at the target points in each of the pad regions based on the pitch distance of the target points in each of the pad regions being greater than the third reference value and less than or equal to a fourth reference value.

6. The method of claim 1, wherein the library pads have a circular shape with a constant diameter.

7. The method of claim 1, wherein the library pads have an elliptical shape having a major axis and a minor axis.

8. The method of claim 1, further comprising detecting warpage on the interposer based on determining the layout of the bump pads.

9. The method of claim 1, further comprising generating a layout drawing of the interposer comprising a layout drawing of the bump pads based on the determined layout of the bump pads.

10. The method of claim 9, wherein the manufacturing of the interposer comprises:
manufacturing a photo mask based on the layout drawing of the bump pads;
forming a conductive film on a side of a base substrate of the interposer; and
patterning the conductive film through a photolithography process based on the photo mask to form the bump pads.

11. A method of designing an interposer, the method comprising:
generating a library comprising information about library pads having different dimensions;
determining a layout of the bump pads corresponding to each of the pad regions, the layout of the bump pads corresponding to each of the pad regions being determined based on selecting a library pad having a target dimension from among the library pads based on a pad interval and a pitch distance of the external connection bumps overlapping each of the pad regions, and placing the selected library pad at target points in each of the pad regions; and
generating a layout drawing of the bump pads based on the determined layout of the bump pads,
wherein the interposer is configured to electrically connect a semiconductor chip mounted on the interposer and external connection bumps attached to bump pads of the interposer, and
wherein the bump pads are spaced apart from each other at a distance greater than the pad interval on a reference plane.

12. The method of claim 11, wherein the library pads included in the library comprise:
a first library pad having a first length in a first direction:
a second library pad having a second length that is greater than the first length in the first direction; and
a third library pad having a third length that is greater than the second length in the first direction.

13. The method of claim 12, further comprising:
determining the first library pad as a bump pad at the target points in each of the pad regions based on the pitch distance of the external connection bumps overlapping each of the pad regions being greater than a first reference value and less than or equal to a second reference value;
determining the second library pad as a bump pad at the target points in each of the pad regions based on the pitch distance of the external connection bumps overlapping each of the pad regions being greater than the second reference value and less than or equal to a third reference value; and
determining the third library pad as a bump pad at the target points in each of the pad regions based on the pitch distance of the external connection bumps overlapping each of the pad regions being greater than the third reference value and less than or equal to a fourth reference value.

14. The method of claim 12, wherein the pad regions comprise a first pad region comprising bump pads configured to transmit data input/output signals to the semiconductor chip and a second pad region comprising bump pads configured to transmit power signals for the semiconductor chip,
wherein the first pad region comprises first target points spaced at a first pitch distance in the first direction,
wherein the second pad region comprises second target points spaced at a second pitch distance that is greater than the first pitch distance in the first direction, and
wherein the determining of the layout of the bump pads comprises determining the first library pad as a bump pad at each of the first target points and determining the second library pad as a bump at each of the second target points.

15. The method of claim 11, further comprising:
determining whether the determined layout of the bump pads conforms to a design rule; and
detecting warpage on the interposer.

16. The method of claim 15, wherein the library pads included in the library respectively has an elliptical shape having a major axis and a minor axis.

17. An interposer comprising:
a base substrate;
an interconnect structure on the base substrate and comprising a conductive interconnect pattern;
through electrodes penetrating the base substrate;
bump pads under the base substrate and spaced apart from each other at an interval greater than a pad interval; and
external connection bumps on the bump pads, respectively;
wherein the bump pads comprises:
first bump pads spaced at a first pitch distance in a first pad region and respectively having a first length in a first direction; and
second bump pads spaced at a second pitch distance that is greater than the first pitch distance in a second pad region and respectively having a second length that is greater than the first length in the first direction.

18. The interposer of claim 17, wherein the interposer is configured to electrically connect a semiconductor chip mounted on the interposer and the external connection bumps,
wherein the first bump pads are configured to transmit data input/output signals for the semiconductor chip, and
wherein the second bump pads are configured to transmit power signals for the semiconductor chip.

19. The interposer of claim 17, wherein the bump pads further comprise third bump pads spaced at a third pitch distance that is greater than the second pitch distance in a third pad region and respectively having a third length that is greater than the second length in the first direction.

20. The interposer of claim 19, wherein the interposer is configured to electrically connect a semiconductor chip mounted on the interposer and the external connection bumps, and
wherein the first bump pads, the second bump pads, and the third bump pads are dummy pads which are not electrically connected to the semiconductor chip.
